(19) United States
(12) Patent Application Publication
(10) Pub. No.: US 2012/0038434 A1
(43) Pub. Date: Feb. 16, 2012

(54) Composite Inductor/Capacitor

(76) Inventor: Michael John Harrison, Christchurch (NZ)

(21) Appl. No.: 13/254,301

(22) PCT Filed: Feb. 17, 2010
(86) PCT No.: PCT/NZ2010/000027

§ 371 Date: Oct. 11, 2011

(30) Foreign Application Priority Data
Mar. 3, 2009 (NZ) 575304

(51) Int. Cl. H03H 7/01

(52) U.S. Cl. 333/185

(57) ABSTRACT

A composite inductor/capacitor including spaced apart sheets of conductive material formed into a spiral with the sheets being spaced apart by a dielectric material with terminals being provided on opposing sheets at opposite ends. A gaped or ungapped ferrite core may form a magnetic loop path about the component Multiple conductive layers may be used to vary capacitance, inductance and load handling. The component may find application in high frequency (above 20 kHz) power converters (such as series-resonant power converters, phase-shifted Zero Voltage Transition full-bridge converters, asymmetric half-bridge ZVT converters or parallel-resonant converters), high frequency induction heater circuits, high frequency welder circuits and the like.

### FIELD OF THE INVENTION

This invention relates to a composite inductor/capacitor. The component may find application in high frequency (above 20 kHz) power converters (such as series-resonant power converters, phase-shifted Zero Voltage Transition full-bridge converters, asymmetric half-bridge ZVT converters or parallel-resonant converters), high frequency induction heater circuits, high frequency welder circuits and the like.

### BACKGROUND OF THE INVENTION

Lumped LC components are used in a range of power applications such as converters to allow control (voltage or current) via switching frequency and provide start up and over current protection.

A conventional capacitor consists of a pair of spiral wound parallel plates spaced by a dielectric element in which terminals are connected to each plate at the same end of the spiral winding. This results in a component that is essentially capacitive with minimal inductance.

A conventional high frequency inductor is formed by winding a wire about a ferrite core with the ends of the wire forming the terminals. Such inductors are essentially inductive with minimal capacitance. For high power, high frequency applications expensive Litz wire may be used to reduce losses at high frequency.

In Liang's paper entitled “Integrated LC Series Resonator for a High Voltage Application” an integrated planar LC element is disclosed. The arrangement is complex and expensive to construct and only provides a first order LC resonant network.

Resonant converters employing higher order resonant networks provide improved controllability and efficiency of the converter (e.g. a second order LCLC resonant network has advantages over a first order LC resonant network). With a first order LC resonant network converter the transfer function is inherently non-linear so to control output voltage (or current) will require different control “gain” (amount of frequency variance) depending on the operating conditions (input voltage, output voltage, output load). An infinite order LCLC . . . resonant network has a linear transfer function providing ease of control.

There is also a desire to reduce cost, losses and component footprint by reducing the number of components required.

It is an object of the invention to provide a component which meets at least some of these goals or which at least provides the public with a useful choice.

### SUMMARY OF THE INVENTION

According to one exemplary embodiment there is provided a composite inductor/capacitor including spaced apart sheets of conductive material formed into a spiral with the sheets being spaced apart by a dielectric material wherein one sheet has a terminal at an outer end of the spiral and another sheet has a terminal at a an inner end of the spiral.

According to another exemplary embodiment there is provided a high frequency power converter including such a composite inductor/capacitor.

### BRIEF DESCRIPTION OF THE DRAWINGS

The accompanying drawings which are incorporated in and constitute part of the specification, illustrate embodiments of the invention by way of example and, together with the general description of the invention given above, and the detailed description of embodiments given below, serve to explain the principles of the invention.

FIG. 1 shows a plan view of conductive sheets before assembly.

FIG. 2 shows a perspective view of a partially assembled component.

FIG. 3 shows a perspective view of one half of a ferrite core.

FIG. 4 shows an embodiment in which 4 conductive sheets are used.

FIG. 5 shows an equivalent circuit to the components shown in FIG. 2.

### DETAILED DESCRIPTION OF EMBODIMENTS OF THE INVENTION

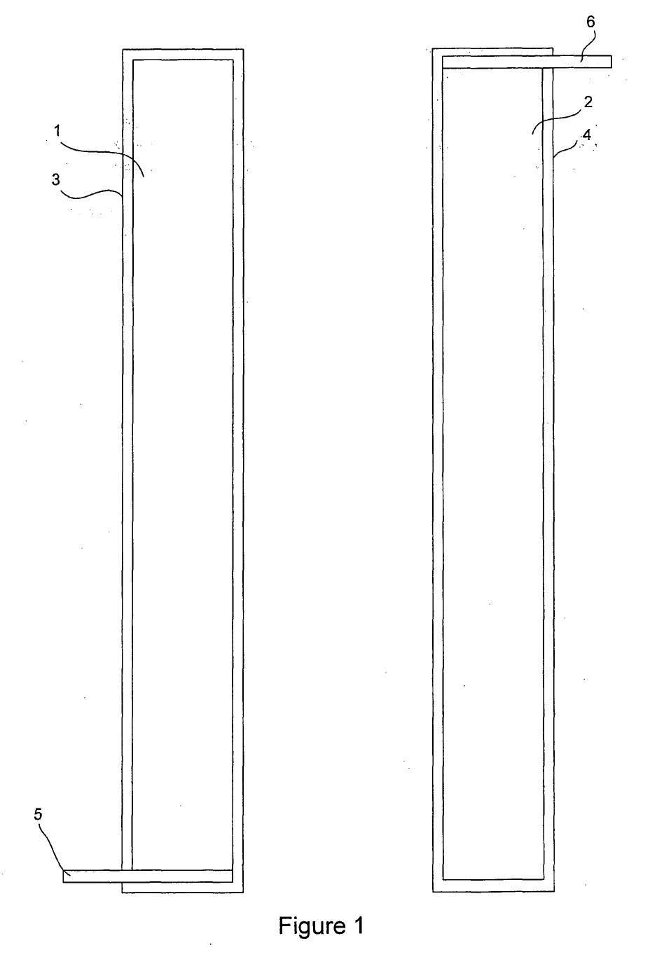

Referring to FIGS. 1-3 the construction of a composite inductor/capacitor according to one embodiment will be described. Conductive sheets 1 and 2 are provided upon dielectric insulating layers 3 and 4. A first terminal 5 is provided at one end of conductive sheet 1 and a second termination 6 is provided at the opposite end of conductive sheet 2.

Conductive sheets 1 and 2 are preferably formed of a conductive metal such as copper or aluminium. Conductive sheets 1 and 2 are much wider than they are thick, preferably at least ten times wider than the thickness so as to provide suitable capacitance. Dielectric insulating layers 3 and 4 may be formed of a dielectric material having a dielectric constant suitable for use in a capacitor such as polypropylene, polystyrene or polyester.

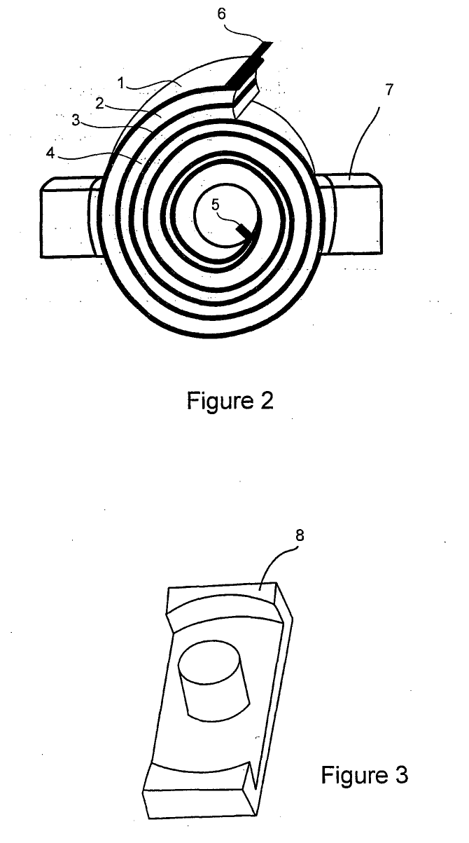

Conductive sheet 1 and dielectric insulator 3 may be translated to the right and placed on top of conductive sheet 2 and dielectric 4 to form a stacked assembly of conductive sheets 1 and 2 and insulating layers 3 and 4 in which terminal 5 is provided at one end of the assembly and terminal 6 is provided at the other end. This assembly may then be wound into a spiral of the form shown in FIG. 2 and placed within one half of a ferrite core 7. An identical ferrite core half is shown in FIG. 3 which may be mated with ferrite core 7 to form a magnetic loop path through the centre of the spiral and about the spiral wound assembly. The ferrite core may be gapped or un-gapped. For extremely high frequency applications a physical core may not be required (an “air cored” construction). In other applications mu-metal, powdered iron or powdered ferrite could be employed.

As terminals 5 and 6 are provided at opposite ends of the spiral the component provides significant inductance as well as capacitive coupling. This allows one component to replace capacitive and conductive components.

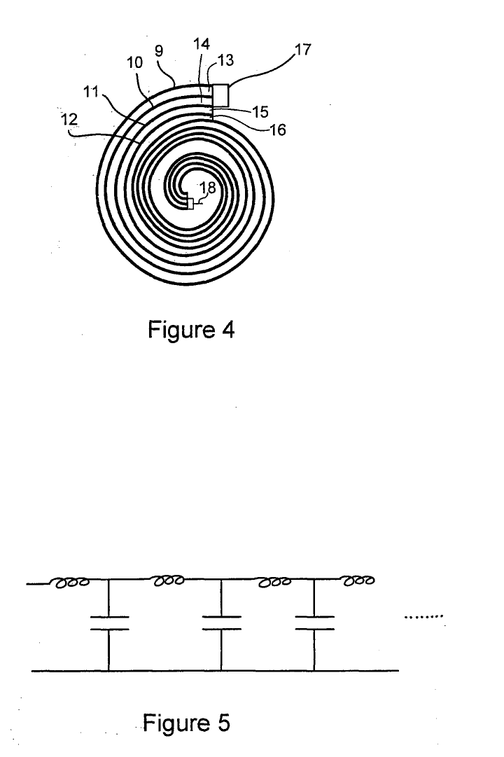

FIG. 4 shows an alternative embodiment in which four conductive sheets 9 to 12 are spaced apart by dielectric insulating layers 13 to 16. Conductive sheets 9 and 11 are connected to a common terminal 17 at one end and conductive sheets 10 and 12 are connected to a common terminal 18 at the other end. The conductive sheets 9 and 11 and 10 and 12 are preferably interleaved. A component using four conductive sheets will have one quarter of the inductance of a two conductive sheet construction and be able to carry twice the current of a two conductor sheet construction. It will be appreciated that further conductive layers may be used where a higher capacitance or lower inductance is required. Whilst pairs of additional sheets are preferred for balance odd numbers of conductive layers could also be employed.

FIG. 5 shows an equivalent circuit to the components shown in FIG. 2, It will be seen that the component is an equivalent to an LC network of infinite order. This allows a single component to be employed where multiple capacitors and inductors would be required to achieve equivalent results.

The composite inductor/capacitor of the invention is particularly suitable for high frequency power applications with switching frequencies above 20 kHz and power ranges in the 10 W-10 kW range. Whilst values of capacitance and inductance can be varied by material dimensions, properties and layout for particular application capacitance values may typically be in the 1 nF to 100 nF range and inductance values may typically be in the 1 uH to 100 uH range.

The component may find application in high frequency (above 20 kHz) power converters such as series-resonant power converters, phase-shifted Zero Voltage Transition full-bridge converters, asymmetric half-bridge ZVT converters or parallel-resonant converters or high frequency induction heater circuits or high frequency welder circuits and the like.

There is thus provided a composite inductor/capacitor allowing a single component to be used in place of two or more capacitive or inductive components, thus reducing costs, losses and component footprint. When using power convertors the fact that a component is modeled by an infinite order LC circuit provides a linear transfer function, greatly simplifying control of the convertor.

While the present invention has been illustrated by the description of the embodiments thereof, and while the embodiments have been described in detail, it is not the intention of the Applicant to restrict or in any way limit the scope of the appended claims to such detail. Additional advantages and modifications will readily appear to those skilled in the art. Therefore, the invention in its broader aspects is not limited to the specific details, representative apparatus and method, and illustrative examples shown and described. Accordingly, departures may be made from such details without departure from the spirit or scope of the Applicant's general inventive concept.

1. A composite inductor/capacitor including spaced apart sheets of conductive material formed into a spiral with the sheets being spaced apart by a dielectric material wherein one sheet has a terminal at an outer end of the spiral and another sheet has a terminal at a an inner end of the spiral.

2. A composite inductor/capacitor as claimed in claim 1 including a ferrite core forming a magnetic loop path through the centre of the spiral and about, the exterior of the sheets.

3. A composite inductor/capacitor as claimed in claim 2 wherein the ferrite core is gapped.

4. A composite inductor/capacitor as claimed in claim any one of the preceding claims including a pair of conductive sheets having interconnected terminals at an outer end of the spiral and a pair of conductive sheets having interconnected terminals at an outer end of the spiral.

5. A composite inductor/capacitor as claimed in any one of the preceding claims including a three or more conductive sheets having interconnected terminals at an outer end of the spiral and three or more conductive sheets having interconnected terminals at an outer end of the spiral.

6. A composite inductor/capacitor as claimed in any one of the preceding claims wherein the conductive sheets are much wider in a direction along the axis of the spiral than normal to the axis of the spiral.

7. A composite inductor/capacitor as claimed in any one of the preceding claims wherein the conductive sheets are more than 10 times wider in a direction along the axis of the spiral than normal to the axis of the spiral

8. A composite inductor/capacitor as claimed in any one of the preceding claims configured and arranged for operation above 20 kHz.

9. A composite inductor/capacitor as claimed in any one of the preceding claims having a capacitance of about 1 nF to 100 nF.

10. A composite inductor/capacitor as claimed in any one of the preceding claims having an inductance of about 1 uH to 100 uH.

11. A composite inductor/capacitor as claimed in any one of the preceding claims having a power rating of 10 W to 10 kW.

12. A composite inductor/capacitor as claimed in any one of the preceding claims wherein the conductive sheets are formed of copper.

13. A composite inductor/capacitor as claimed in any one of the preceding claims wherein the conductive sheets are formed of Aluminium.

14. A high frequency power converter including a composite inductor/capacitor as claimed in any one of the preceding claims.

15. A high frequency power converter as claimed in claim 14 that is series-resonant.
